(19) United States
(12) Patent Application Publication
(10) Pub. No.: US 2024/0063030 A1
(43) Pub. Date: Feb. 22, 2024

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Hung-Pin Chang, New Taipei City (TW); Han-Yi Lu, Hsinchu (TW); Wei-Cheng Wu, Hsinchu City (TW); Der-Chyang Yeh, Hsin-Chu (TW)

(73) Assignee: Taiwan Semiconductor Manufacturing Company, Ltd., Hsinchu (TW)

(21) Appl. No.: 17/889,381

(22) Filed: Aug. 16, 2022

(51) Int. Cl. H01L 21/48; H01L 23/498; H01L 23/538; H01L 23/00; H01L 23/31; H01L 23/495; H01L 21/768

(52) U.S. Cl. CPC H01L 21/4857; H01L 23/49816; H01L 23/538; H01L 23/562; H01L 23/3171; H01L 23/49503; H01L 21/76871

(57) ABSTRACT

Provided is a semiconductor device including a substrate, an interconnect structure, a first passivation layer, a stress buffer layer, a pad structure, and a second passivation layer. The interconnect structure is disposed on the substrate. The first passivation layer and the stress buffer layer are disposed on the interconnect structure. The pad structure includes: a lower portion embedded in the first passivation layer and the stress buffer layer, and laterally wrapped by the first passivation layer and the stress buffer layer; and an upper portion on the lower portion. The upper portion has a periphery laterally offset outward from a periphery of the lower portion, so that a bottom surface of the upper portion contacts a top surface of the stress buffer layer. The second passivation layer is disposed on the stress buffer layer and laterally wraps the upper portion of the upper portion of the pad structure.

### BACKGROUND

The semiconductor integrated circuit (IC) industry has experienced rapid growth. Technological advances in IC materials and design have produced generations of ICs. Each generation has smaller and more complex circuits than the previous generation.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, these advances have increased the complexity of processing and manufacturing ICs. Since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1F are cross-sectional views of a method of forming a semiconductor device in accordance with a first embodiment.

FIG. 2 is a cross-sectional view of a semiconductor device in accordance with a second embodiment.

FIG. 3A to FIG. 3B are cross-sectional views of a method of forming a semiconductor device in accordance with a third embodiment.

FIG. 3C is a cross-sectional view of a package structure in accordance with some embodiments.

FIG. 4A to FIG. 4D are cross-sectional views of a method of forming a semiconductor device in accordance with a fourth embodiment.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

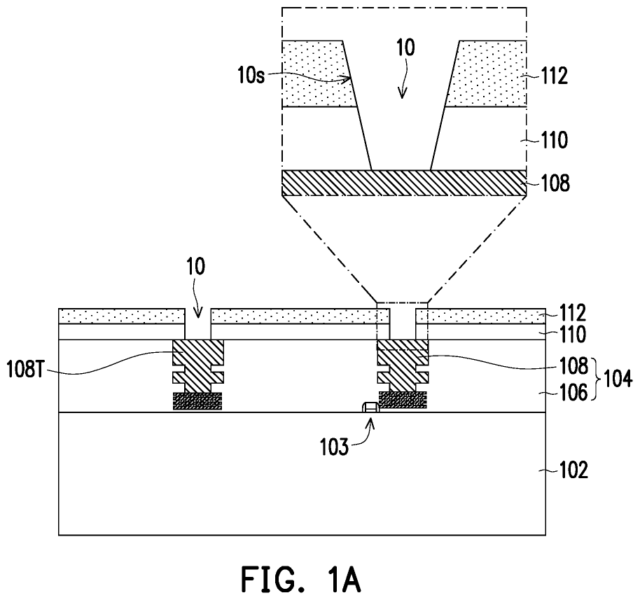

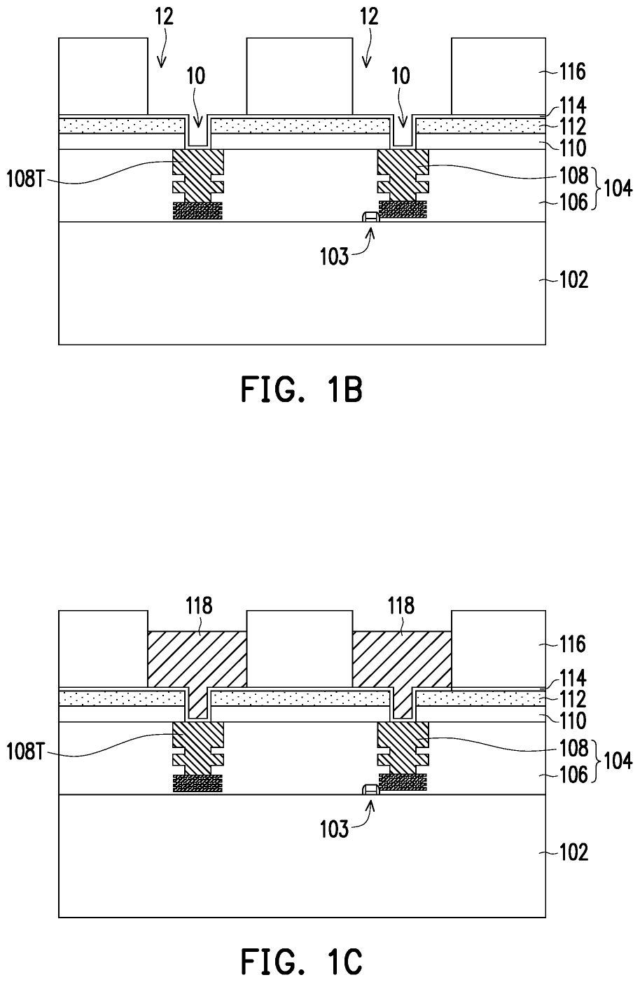

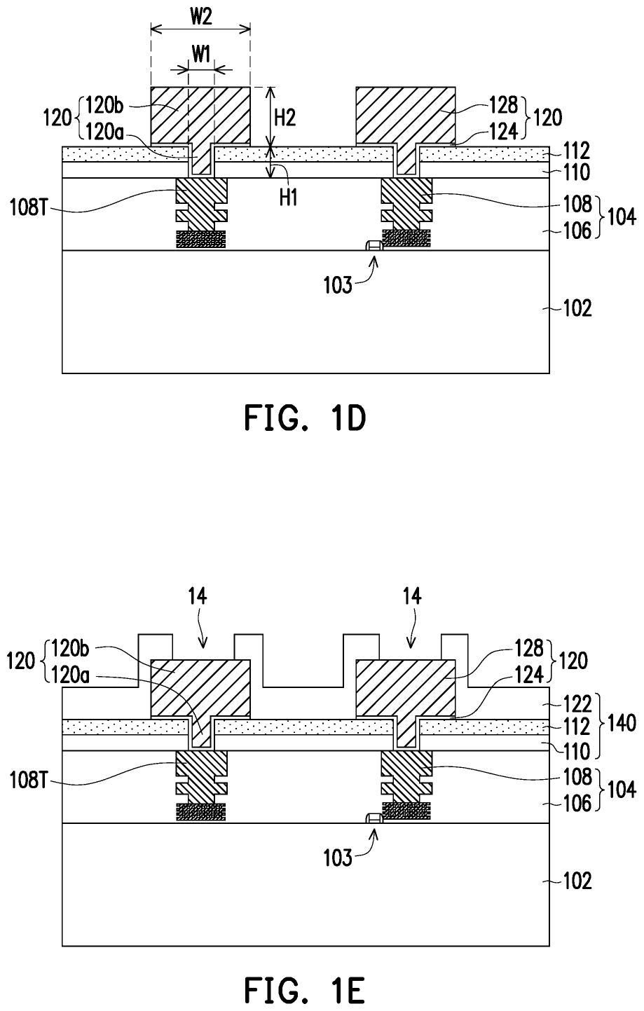

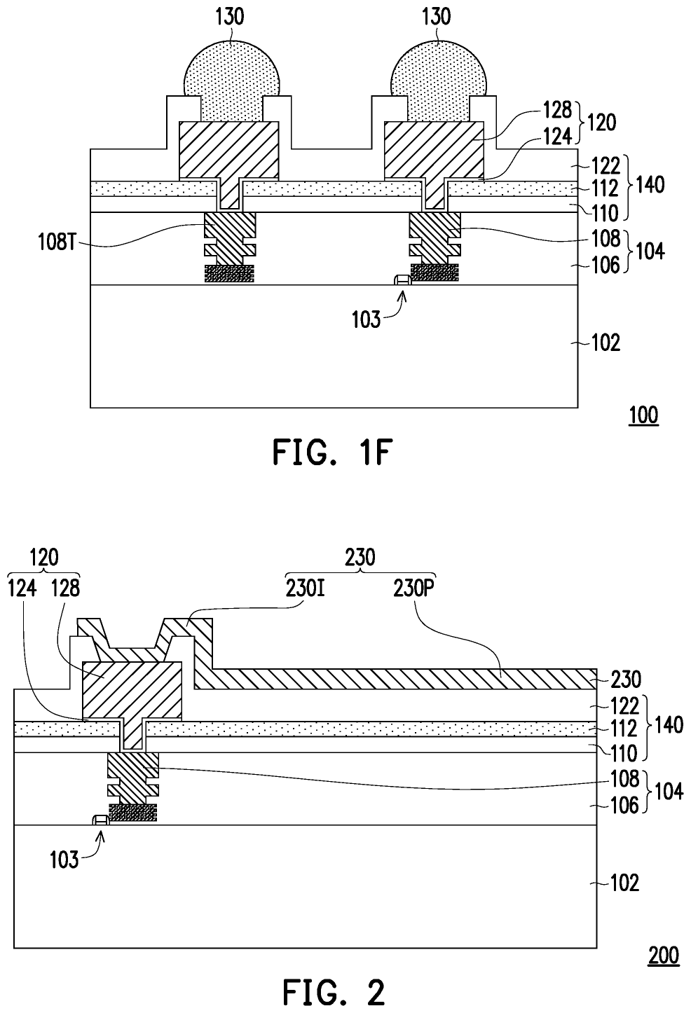

FIG. 1A to FIG. 1F are cross-sectional views of a method of forming a semiconductor device in accordance with a first embodiment.

Referring to FIG. 1A, a semiconductor substrate 102 is provided. In some embodiments, the semiconductor substrate 102 may include silicon or other semiconductor materials. Alternatively, or additionally, the semiconductor substrate 102 may include other elementary semiconductor materials such as germanium. In some embodiments, the semiconductor substrate 102 is made of a compound semiconductor such as silicon carbide, gallium arsenic, indium arsenide or indium phosphide. In some embodiments, the semiconductor substrate 102 is made of an alloy semiconductor such as silicon germanium, silicon germanium carbide, gallium arsenic phosphide, or gallium indium phosphide. In some embodiments, the semiconductor substrate 102 includes an epitaxial layer. For example, the semiconductor substrate 102 has an epitaxial layer overlying a bulk semiconductor.

In some embodiments, a device region 103 is formed on the semiconductor substrate 102 in a front-end-of-line (FEOL) process. The device region 103 includes a wide variety of devices. In some embodiments, the devices comprise active components, passive components, or a combination thereof. In some embodiments, the devices may include integrated circuits devices. The devices are, for example, transistors, capacitors, resistors, diodes, photodiodes, fuse devices, or other similar devices. In some embodiments, the device region 103 includes a gate structure, source/drain regions, and isolation structures, such as shallow trench isolation (STI) structures (not shown). The device region 103 shown in FIG. 1A are merely examples, and other structures may be formed in the device region 103. In the device region 103, various N-type metal-oxide semiconductor (NMOS) and/or P-type metal-oxide semiconductor (PMOS) devices, such as transistors or memories and the like, may be formed and interconnected to perform one or more functions. Other devices, such as capacitors, resistors, diodes, photodiodes, fuses and the like may also be formed on the semiconductor substrate 102. The functions of the devices may include memory, processors, sensors, amplifiers, power distribution, input/output circuitry, or the like.

After forming the device region 103, an interconnect structure 104 is formed over the semiconductor substrate 102. In detail, the interconnect structure 104 includes a dielectric layer 106 and a plurality of metal features 108. The metal features 108 are formed in the dielectric layer 106 and electrically connected with each other. A portion of the metal features 108, such as a top metal feature 108T, is exposed by the dielectric layer 106. In some embodiments, the dielectric layer 106 includes an inner-layer dielectric (ILD) layer on the semiconductor substrate 102, and at least one inter-metal dielectric (IMD) layer over the inner-layer dielectric layer. In some embodiments, the dielectric layer 106 includes silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), polyimide, and/or a combination thereof. In some other embodiments, the dielectric layer 106 includes low-k dielectric materials that have a dielectric constant less than 4. Examples of low-k dielectric materials include BLACK DIAMOND® (Applied Materials of Santa Clara, Calif.), Xerogel, Aerogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), and/or a combination thereof. In alternative embodiments, the dielectric layer 106 include one or more dielectric materials. In some embodiments, the dielectric layer 106 is formed by any suitable method, such as chemical vapor deposition (CVD), spin-on, or the like. Although the dielectric layer 106 illustrated in FIG. 1A is a single-layered structure, the embodiments of the present disclosure are not limited thereto. In other embodiments, the dielectric layer 106 may be a bi-layered structure or multi-layered structure.

In some embodiments, the metal features 108 include plugs and metal lines. The plugs may include contacts formed in the inner-layer dielectric layer, and vias formed in the inter-metal dielectric layer. The contacts are formed between and in connect with the substrate 102 and a bottom metal line. The vias are formed between and in connect with two metal lines. The metal features 108 may be made of tungsten (W), copper (Cu), copper alloys, aluminum (Al), aluminum alloys, or a combination thereof. In some alternatively embodiments, a barrier layer (not shown) may be formed between the metal features 108 and the dielectric layer 106 to prevent the material of the metal features 108 from migrating to the device region 103. A material of the barrier layer includes tantalum, tantalum nitride, titanium, titanium nitride, cobalt-tungsten (CoW) or a combination thereof, for example.

As shown in FIG. 1A, a first passivation layer 110 is formed on the interconnect structure 104. The first passivation layer 110 may cover the dielectric layer 106 and the top metal feature 108T. In some embodiments, the first passivation layer 110 includes an inorganic dielectric material, such as silicon oxide, silicon nitride, silicon oxynitride, silicon carbide, silicon carbonitride, silicon oxycarbide, tetra-ethyl-ortho-silicate (TEOS) oxide, the like, or a combination thereof and is formed by a suitable process such as plasma-enhanced CVD (PECVD), high-density plasma CVD (HDPCVD) or the like. In one embodiment, the first passivation layer 110 has a thickness between about 5000 Å and about 15000 Å. Although the first passivation layer 110 illustrated in FIG. 1A is a single-layered structure, the disclosure is not limited thereto. In other embodiments, the first passivation layer 110 may be a bi-layered structure or multi-layered structure formed of inorganic dielectric material.

Next, a stress buffer layer 112 is formed on the first passivation layer 110. In some embodiments, the stress buffer layer 112 includes a polymer material, such as polyimide, polybenzoxazole (PBO), benzocyclobutene (BCB), the like, or a combination thereof and is formed by a suitable process spin coating, laminating, or the like. Although the stress buffer layer 112 illustrated in FIG. 1A is a single-layered structure, the disclosure is not limited thereto. In other embodiments, the stress buffer layer 112 may be a bi-layered structure or multi-layered structure formed of inorganic dielectric material. The stress buffer layer 112 and the first passivation layer 110 may have different materials with different physical properties. For example, the stress buffer layer 112 may have a Young's modulus less than a Young's modulus of the first passivation layer 110, which means the stress buffer layer 112 is softer or more elastic than the first passivation layer 110. In some embodiments, the Young's modulus of the stress buffer layer 112 is between about 2 GPa and about 6 GPa, and more specifically, between about 4.5 GPa and about 5.5 GPa, such as about 5.2 GPa. Additionally, the stress buffer layer 112 may have a tensile strength between 100 MPa and about 250 MPa, and more specifically, between about 200 MPa and about 250 MPa, such as about 221 MPa. Further, the stress buffer layer 112 may have an elongation between about 5% and about 50%, and more specifically, between about 30% and about 50%, such as about 40%, before rupture. In one embodiment, the stress buffer layer 112 has a thickness between about 4 lam and about 6 μm.

After forming the stress buffer layer 112, an opening 10 may be formed in the stress buffer layer 112 and the first passivation layer 110. In some embodiments, the opening 10 penetrates through the stress buffer layer 112 and the first passivation layer 110 to expose a portion of the top metal feature 108T in the interconnect structure 104. Specifically, the opening 10 may be formed by an etching process, such as a reactive ion etching (RIE) process, a neutral beam etching (NBE) process, an inductive coupled plasma (ICP) etching process, the like, or a combination thereof. The etching process may be anisotropic. The etchants used in the etching process may include a fluorine reactive gas, such as, a carbon-fluoro-based etchant (CxFy), NF₃, or the like. Other process gases may be used in combination with the carbon-fluoro-based etchants, such as, oxygen (O₂), nitrogen (N₂), argon (Ar), combinations thereof, or the like. It should be noted that, in some embodiments, since the stress buffer layer 112 and the first passivation layer 110 have different materials, the opening 10 may have a horizontal cross-sectional shape that is variant under translation along a vertical direction respective to the top surface of the semiconductor substrate 102. Specifically, as shown in the enlarged view of FIG. 1A, a sidewall 10s of the opening 10 may be an inclined sidewall or a tapered sidewall. That is, the opening 10 has a wider upper width in the stress buffer layer 112 and a narrower lower width in the first passivation layer 110, so that the opening 10 is inverted trapezoidal in cross section. Alternatively, the opening 10 with a uniform horizontal cross-sectional shape or a uniform width is within the contemplated scope of the disclosure. For simplify, the opening 10 shown in the following figures all has a uniform width. In some embodiments, the horizontal cross-sectional shape of the opening 10 may be circular, elliptical, polygonal, or of a modified polygonal shape having rounded corners.

Referring to FIG. 1B, a seed material 114 is formed on the stress buffer layer 112. In detail, the seed material 114 may conformally cover a surface of the opening 10 and be in contact with the top metal feature 108T of the interconnect structure 104 at the bottom of the opening 10. In some embodiments, the seed material 114 is formed by any suitable deposition method such as PVD (e.g., sputtering), CVD, or the like. In some embodiments, the seed material 114 is a metal layer, which may be a single layer or a composite layer including a plurality of sub-layers formed of different materials. In the present embodiment, the seed material 114 is, for example, a titanium/copper composited layer, wherein the sputtered titanium thin film is in contact the top metal feature 108T, and the sputtered copper thin film is then formed over the sputtered titanium thin film. In some alternative embodiments, the seed material 114 may be other suitable composited layer such as metal, alloy, barrier metal, or a combination thereof.

After forming the seed material 114, a mask pattern 116 is formed on the seed material 114. In detail, the mask pattern 116 may have an opening 12 corresponding to the opening 10. The opening 12 may expose the seed material 114 on the opening 10. In some embodiments, the mask pattern 116 includes photoresist, such as a positive photoresist or a negative photoresist, and may be formed by any suitable method, such as spin-coating.

Referring to FIG. 1B and FIG. 1C, a conductive material 118 is formed on the seed material 114 by a plating process, for example. In detail, the conductive material 118 may be filled in the openings 10 and 12. In some embodiments, the conductive material 118 includes copper or other suitable metal, for example. In some alternatively embodiments, the conductive material 118 is formed by PVD (e.g., sputtering), CVD, or the like. In some alternative embodiments, a height of the conductive material 118 is less than a height of the mask pattern 116. However, the embodiments of the present invention are not limited thereto.

Referring to FIG. 1C and FIG. 1D, the mask pattern 116 is removed and the seed material 114 uncovered by the conductive material 118 is also removed, thereby accomplishing a pad structure 120, as shown in FIG. 1D. In detail, the pad structure 120 may include a seed layer 124 and a conductive layer 128 formed on the seed layer 124. The seed layer 124 may conformally cover the surface of the opening 10 and extend to cover a portion of a top surface of the stress buffer layer 112. That is, the seed layer 124 may extend between the conductive layer 128 and the top surface of the stress buffer layer 112, while the seed layer 124 does not extend to cover the sidewall of the conductive layer 128 over the stress buffer layer 112. On the other hands, the pad structure 120 may include a lower portion 120a and an upper portion 120b disposed on the lower portion 120a. The lower portion 120a may be embedded in the first passivation layer 110 and the stress buffer layer 112, and laterally wrapped by the first passivation layer 110 and the stress buffer layer 112. The upper portion 120b may have a periphery laterally offset outward from a periphery of the lower portion 120a, so that a bottom surface of the upper portion 120b may be in contact with a top surface of the stress buffer layer 112. In other word, the lower portion 120a may have a width W1 less than a width W2 of the upper portion 120b. In some embodiments, the width W1 of the lower portion 120a is between about 1 μm and about 4 μm, and the width W2 of the upper portion 120b is between about 5 ium and about 50 ium, and a ratio (W2/W1) of the width W2 of the upper portion 120b to the width W1 of the lower portion 120a is between about 1.2 and about 50. In some embodiments, the lower portion 120a has a height H1 between about 5000 Å and about 15000 Å, and the upper portion 120b has a height H2 between about 2 μm and about 6 ium, and a ratio (H2/H1) of the height H2 of the upper portion 120b to the height H1 of the lower portion 120a is between about 1.3 and about 12.

Referring to FIG. 1D and FIG. 1E, a second passivation layer 122 is formed on the stress buffer layer 112 to laterally wrap the upper portion 120b of the pad structure 120. In some embodiments, the second passivation layer 122 further extends to cover a first portion (e.g., edge portion) of the top surface of the pad structure 120, while the second passivation layer 122 has an opening 14 exposing a second portion (e.g., center portion) of the top surface of the pad structure 120. In some embodiments, the second passivation layer 122 includes an inorganic dielectric material, such as silicon oxide, silicon nitride, silicon oxynitride, silicon carbide, silicon carbonitride, silicon oxycarbide, tetra-ethyl-ortho-silicate (TEOS) oxide, the like, or a combination thereof and is formed by a suitable process such as plasma-enhanced CVD (PECVD), high-density plasma CVD (HDPCVD) or the like. In one embodiment, the second passivation layer 122 has a thickness between about 1 μm and about 3 μm. Although the second passivation layer 122 illustrated in FIG. 1E is a single-layered structure, the disclosure is not limited thereto. In other embodiments, the second passivation layer 122 may be a bi-layered structure or multi-layered structure formed of inorganic dielectric material.

In the present embodiment, the first passivation layer 110 and the second passivation layer 122 have the same material, such as silicon nitride. The material of the stress buffer layer 112 may be different from the material of the first and second passivation layers 110, 122. For example, the stress buffer layer 112 is made of polyimide, while the first and second passivation layers 110, 122 are made of silicon nitride. In some embodiments, the stress buffer layer 112 may have the Young's modulus less than the Young's modulus of the first passivation layer 110 and/or the second passivation layer 122, which means the stress buffer layer 112 is softer or more elastic than the first passivation layer 110 and/or the second passivation layer 122.

In some embodiments, the pad structure 120 may be referred to as a redistribution line (RDL) structure to provide the electrical routing on the interconnect structure 104 and/or on the passivation layer 110. The thick pad structure 120 (e.g., thick copper RDL) may facilitate reduce the resistance and increase the signal transmission speed. However, in the prior art, the thick copper pad structure places excessive stress on the underlying passivation layer, so that the contact interface between the passivation layer and the thick copper pad structure will be cracked. It should be noted that, in the present embodiment, a relatively soft stress buffer layer 112 is inserted between the first passivation layer 110 and the second passivation layer 122, so that the stress buffer layer 112 is able to absorb the stress generated by the thick copper pad structure 120, thereby avoiding the crack and delamination issues at the contact interface between the stress buffer layer 112 and the thick copper pad structure 120. As such, the reliability of the semiconductor device 100 of the present embodiment can be effectively improved. Here, the stress buffer layer 112 may also be referred to as a stress absorption layer or a stress relief layer. Alternatively, the stacked structure of the first passivation layer 110, the stress buffer layer 112, and the second passivation layer 122 may constitute a protection structure 140. As shown in FIG. 1E, the protection structure 140 may laterally wrap and attach the pad structure 120, and hence provides better mechanical strength to the pad structure 120 and becomes applicable to a larger metal-to-metal contact area.

Referring to FIG. 1E and FIG. 1F, a bump structure 130 is formed in the opening 14 to contact the second portion of the top surface of the pad structure 120, thereby accomplishing a semiconductor device 100 with the stress buffer layer 112 between the passivation layers 110 and 122. In some embodiments, the bump structure 130 may be a controlled collapse chip connection (C4) and/or may comprise a material such as solder, tin, or other suitable materials, such as silver, lead-free tin, or copper. In an embodiment in which the bump structure 130 is a tin solder bump, the bump structure 130 may be formed by initially forming a layer of tin through evaporation, electroplating, printing, solder transfer, ball placement, etc. Once a layer of tin has been formed on the structure, a reflow may be performed in order to shape the material into the desired bump shape. Other bump structures may be used. For example, a metal pillar with a solder connector may also be used.

FIG. 2 is a cross-sectional view of a semiconductor device in accordance with a second embodiment.

Referring to FIG. 2, a semiconductor device 200 of the second embodiment is similar to the semiconductor device 100 of the first embodiment illustrated in FIG. 1F. A main difference therebetween lies in that the semiconductor device 200 has a post-passivation interconnect (PPI) line 230 to replace the bump structure 130 of the semiconductor device 100. In detail, the PPI line 230 is formed in the opening 14 (FIG. 1E) to contact the second portion of the top surface of the pad structure 120, and extends on a top surface of the second passivation layer 230. The PPI line 230 may include an interconnect line region 2301 and a landing pad region 230P. The interconnect line region 2301 and the landing pad region 230P may be formed simultaneously, and may be formed of a same conductive material. A bump feature will be formed over and electrically connected to the landing pad region 230P in subsequent processes. The PPI line 230 may include, but is not limited to, for example copper, aluminum, copper alloy, or other mobile conductive materials by using plating, electroless plating, sputtering, CVD, or the like. In some embodiments, the PPI line 230 may further include a nickel-containing layer (not shown) on top of a copper-containing layer. In some embodiments, the PPI line 230 may also function as a power line, redistribution line (RDL), inductor, capacitor or any passive component. Through the routing of PPI line 230, the landing pad region 230P may be, or may not be, directly over the pad structure 120.

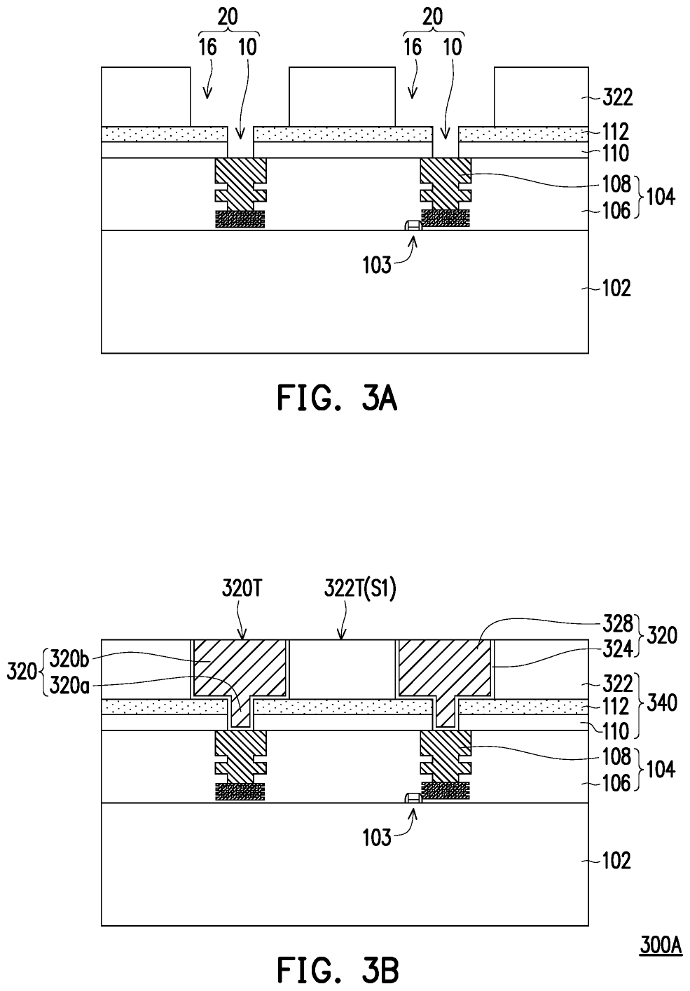

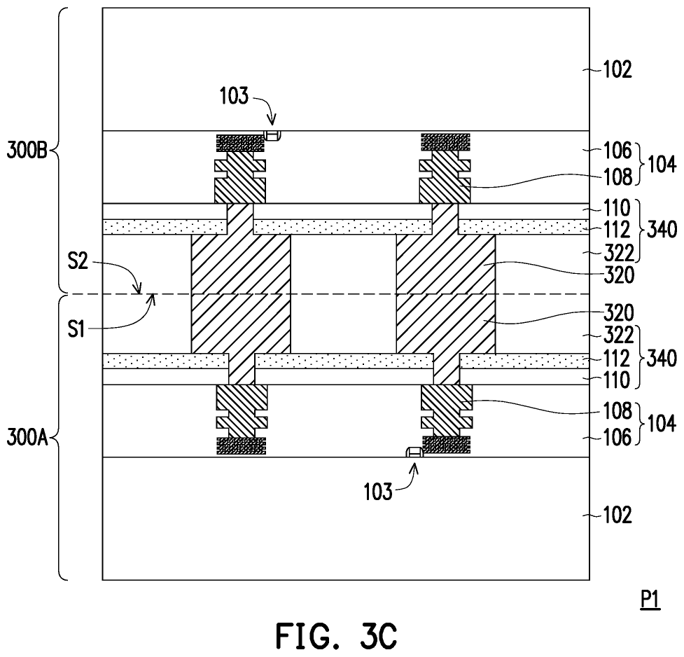

FIG. 3A to FIG. 3B are cross-sectional views of a method of forming a semiconductor device in accordance with a third embodiment.

FIG. 3A continues the structure of FIG. 1A, a second passivation layer 322 is then formed on the stress buffer layer 112. In detail, the second passivation layer may have an opening 16 communicating with the underlying opening 10 to form a composite opening 20. The upper opening 16 has a width greater than a width of the lower opening 10, so that a portion of the top surface of the stress buffer layer 112 is exposed by the upper opening 16. In some embodiments, the composite opening 20 may be referred to as a dual damascene opening in which the lower opening 10 may be referred to as a via opening and the upper opening 16 may be referred to as a trench opening. In some embodiments, the f second passivation layer 322 includes an inorganic dielectric material, such as silicon oxide, silicon nitride, silicon oxynitride, silicon carbide, silicon carbonitride, silicon oxycarbide, tetra-ethyl-ortho-silicate (TEOS) oxide, the like, or a combination thereof and is formed by a suitable process such as plasma-enhanced CVD (PECVD), high-density plasma CVD (HDPCVD) or the like. In one embodiment, the second passivation layer 322 has a thickness between about 2 μm and about 6 μm. Although the second passivation layer 322 illustrated in FIG. 3A is a single-layered structure, the disclosure is not limited thereto. In other embodiments, the second passivation layer 322 may be a bi-layered structure or multi-layered structure formed of inorganic dielectric material.

Referring to FIG. 3A and FIG. 3B, a pad structure 320 is formed in the composite opening 20. In some embodiments, the pad structure 320 is formed by following steps. First, a seed material is formed to conformally cover a surface of the composite opening 20 and the top surface of the second passivation layer 322. A conductive material is then formed on the seed material to fill in the composite opening 20. Next, a planarization process is performed to remove an excess portion of the seed material and the conductor material on the second passivation layer 322, thereby forming the pad structure 320 in the composite opening 20. In some embodiments, the planarization process includes a chemical-mechanical polishing (CMP) process, a mechanical grinding process, a fly cutting process or an etching back process. After the planarization process, a semiconductor device 300A is accomplished.

Specifically, as shown in FIG. 3B, the pad structure 320 may include a seed layer 324 and a conductive layer 328 formed on the seed layer 324. The conductive layer 328 is formed in the composite opening 20. The seed layer 324 may extend between the conductive layer 328 and the second passivation layer 322, extend between the conductive layer 328 and the stress buffer layer 112, and extend between the conductive layer 328 and the first passivation layer 110. That is, the seed layer 324 may completely cover the sidewall and the bottom surface of the conductive layer 328, while exposing the top surface of the conductive layer 328. On the other hands, the pad structure 320 may include a lower portion 320a and an upper portion 320b disposed on the lower portion 320a. The lower portion 320a may be embedded in the first passivation layer 110 and the stress buffer layer 112, and laterally wrapped by the first passivation layer 110 and the stress buffer layer 112. The upper portion 320b may have a periphery laterally offset outward from a periphery of the lower portion 320a, so that a bottom surface of the upper portion 320b may be in contact with a top surface of the stress buffer layer 112. In other word, the lower portion 320a may have a width less than a width 3 of the upper portion 320b. In addition, the stacked structure of the first passivation layer 110, the stress buffer layer 112, and the second passivation layer 322 may constitute a protection structure 340. As shown in FIG. 3B, the protection structure 340 may laterally wrap and attach the pad structure 320, and hence provides better mechanical strength to the pad structure 320 and becomes applicable to a larger metal-to-metal contact area.

In the present embodiment, the first passivation layer 110 and the second passivation layer 322 have the same material, such as silicon nitride. The material of the stress buffer layer 112 may be different from the material of the first and second passivation layers 110, 322. For example, the stress buffer layer 112 is made of polyimide, while the first and second passivation layers 110, 322 are made of silicon nitride. In some embodiments, the stress buffer layer 112 may have the Young's modulus less than the Young's modulus of the first passivation layer 110 and/or the second passivation layer 322, which means the stress buffer layer 112 is softer or more elastic than the first passivation layer 110 and/or the second passivation layer 322. In this case, a relatively soft stress buffer layer 112 is inserted between the first passivation layer 110 and the second passivation layer 322, so that the stress buffer layer 112 is able to absorb the stress generated by the thick copper pad structure 320, thereby avoiding the crack and delamination issues at the contact interface between the stress buffer layer 112 and the thick copper pad structure 320. As such, the reliability of the semiconductor device 300A of the present embodiment can be effectively improved.

It should be noted that, after the planarization process, a top surface 320T of the pad structure 320 may be substantially level with a top surface 322T of the second passivation layer 322. In such embodiment, a bondable topography variation (BTV) of a top surface S1 of the semiconductor device 300A may be less than 10 nm per 1 mm range to ease to directly bond to other dies or chips. Here, the bondable topography variation (BTV) is referred as a height difference between a highest point and a lowest point of the top surface S1 of the semiconductor device 300A. In some alternative embodiments, a bondable topography slope (BTS) of the top surface S1 of the semiconductor device 300A may be less than 0.001. Here, the bondable topography slope (BTS) is referred as a ratio of the vertical variation to the horizontal variation between the highest point and the lowest point of the top surface S1 of the semiconductor device 300A.

FIG. 3C is a cross-sectional view of a package structure in accordance with some embodiments.

FIG. 3C continues the structure of FIG. 3B, another semiconductor device 300B is then provided. In some embodiments, the semiconductor device 300B is similar to the semiconductor device 300A, namely, the arrangement, material and forming method of the semiconductor device 300B are similar to those of the semiconductor device 300A, which are described in the above paragraphs, and the details thereof are omitted here. In some embodiments, the semiconductor devices 300A and 300B may have the same function or different functions. The semiconductor devices 300A and 300B may be semiconductor wafer, chip, die, or the like. For example, the semiconductor devices 300A and 300B may be application-specific integrated circuit (ASIC) chips, analog chips, sensor chips, wireless such as Bluetooth, and radio frequency chips, voltage regulator chips, or memory chips such as dynamic random-access memory (DRAM) chips or static random-access memory (SRAM) chips.

The semiconductor device 300B is flipped, so that a front side S2 of the semiconductor device 300B faces toward the front side (i.e., top surface) S1 of the semiconductor device 300A. The semiconductor device 300A and the semiconductor device 300B may be hybrid bonded together by the application of pressure and heat. In some embodiments, the hybrid bonding involves at least two types of bonding, including metal-to-metal bonding and non-metal-to-non-metal bonding such as dielectric-to-dielectric bonding or fusion bonding. As shown in FIG. 3C, the hybrid bonding may include the upper and lower pad structures 320 bonded by metal-to-metal bonding, and the upper and lower passivation layers 322 bonded by non-metal-to-non-metal bonding. That is, the pad structures 320 of the semiconductor device 300A is in direct contact with the pad structures 320 of the semiconductor device 300B, while the passivation layers 322 of the semiconductor device 300A is in direct contact with the passivation layers 322 of the semiconductor device 300B. After the semiconductor device 300A and the semiconductor device 300B are bonded together, a package structure P1 is accomplished. Although the area of the semiconductor device 300A illustrated in FIG. 3C is the same as the area of the semiconductor device 300B, the embodiments of the present disclosure are not limited thereto. In other embodiments, the area of the upper semiconductor device 300B may be less than the area of the lower semiconductor device 300A, and an encapsulant may be formed to laterally surround the upper semiconductor device 300B after the hybrid bonding.

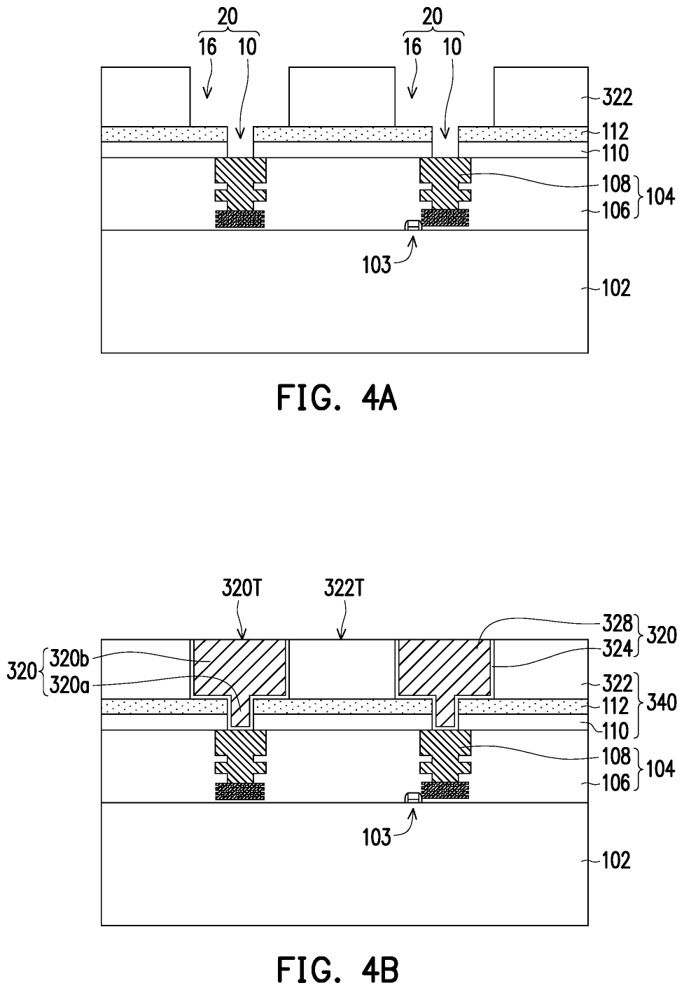

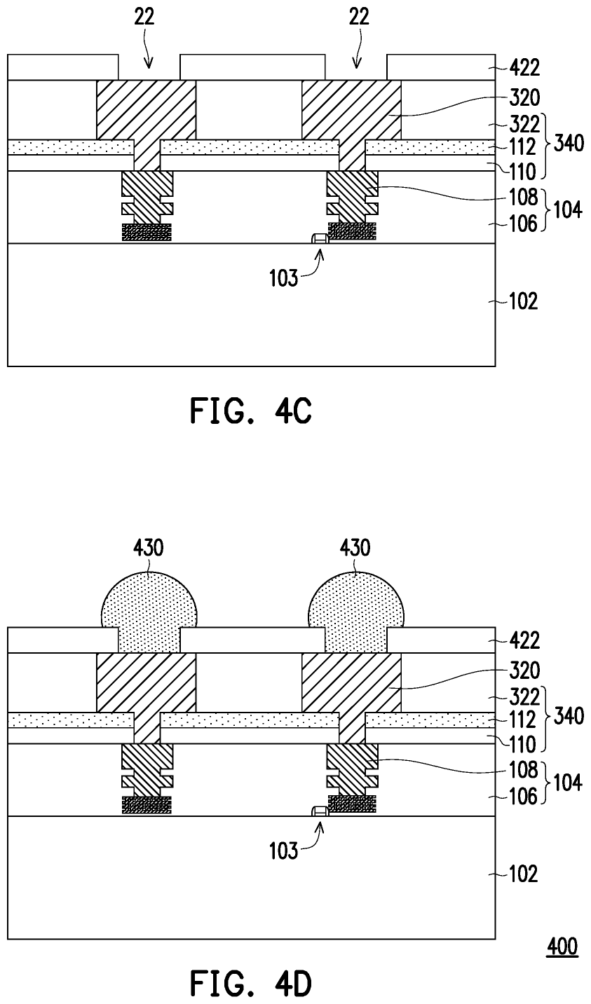

FIG. 4A to FIG. 4D are cross-sectional views of a method of forming a semiconductor device in accordance with a fourth embodiment.

The steps illustrated in FIG. 4A and FIG. 4B are the same as the steps illustrated in FIG. 3A and FIG. 3B, which are described in the above paragraphs, and the details thereof are omitted here. After the planarization process, an additional passivation layer 422 is formed on the passivation layers 322. As shown in FIG. 4C, the passivation layer 422 has an opening 22 exposing a portion of the top surface of the pad structure 320. In some embodiments, the passivation layer 422 includes a polymer material, such as polyimide, polybenzoxazole (PBO), benzocyclobutene (BCB), the like, or a combination thereof and is formed by a suitable process spin coating, laminating, or the like. In the embodiment, the passivation layer 422 and the stress buffer layer have the same material, such as polyimide. That is, the material of the passivation layer 422 is different from the material of the passivation layers 110 and 322. For example, the passivation layer 422 is made of polyimide, while the first and second passivation layers 110, 322 are made of silicon nitride.

Referring to FIG. 4C and FIG. 4D, a bump structure 430 is formed in the opening 22 to contact the portion of the top surface of the pad structure 320, thereby accomplishing a semiconductor device 400. In some embodiments, the bump structure 430 may be a controlled collapse chip connection (C4) and/or may comprise a material such as solder, tin, or other suitable materials, such as silver, lead-free tin, or copper. In an embodiment in which the bump structure 430 is a tin solder bump, the bump structure 430 may be formed by initially forming a layer of tin through evaporation, electroplating, printing, solder transfer, ball placement, etc. Once a layer of tin has been formed on the structure, a reflow may be performed in order to shape the material into the desired bump shape. Other bump structures may be used. For example, a metal pillar with a solder connector may also be used. Alternatively, a PPI line (not shown) may be formed to replace the bump structure 430 of the semiconductor device 400. For the simplicity, the seed layer 324 and the conductive layer 328 in FIG. 4B are simplified to the pad structure 320 with a single-layered structure in FIG. 4C and FIG. 4D.

According to some embodiments, a semiconductor device includes a substrate, an interconnect structure, a first passivation layer, a stress buffer layer, a pad structure, and a second passivation layer. The interconnect structure is disposed on the substrate. The first passivation layer is disposed on the interconnect structure. The stress buffer layer is disposed on the first passivation layer. The pad structure includes: a lower portion embedded in the first passivation layer and the stress buffer layer, and laterally wrapped by the first passivation layer and the stress buffer layer; and an upper portion disposed on the lower portion, wherein the upper portion has a periphery laterally offset outward from a periphery of the lower portion, so that a bottom surface of the upper portion is in contact with a top surface of the stress buffer layer. The second passivation layer is disposed on the stress buffer layer and laterally wraps the upper portion of the upper portion of the pad structure.

According to some embodiments, a method of forming a semiconductor device includes: forming an interconnect structure on a substrate; forming a first passivation layer and a stress buffer layer on the interconnect structure; forming a first opening in the first passivation layer and the stress buffer layer; forming a pad structure on the stress buffer layer, wherein the pad structure has a lower portion in the first opening; and forming a second passivation layer on the stress buffer layer, wherein the second passivation layer laterally wraps an upper portion of the pad structure.

According to some embodiments, a package structure includes a first die and a second die. The first die includes a first pad structure; and a first protection structure laterally wrapping the first pad structure. The first protection structure includes a first stress buffer layer sandwiched between a first passivation layer and a second passivation layer, and the first stress buffer layer has a Young's modulus less than a Young's modulus of the first passivation layer and the second passivation layer. The second die includes a second pad structure. The first die and the second die are bonded together by directly contacting the first pad structure with the second pad structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
an interconnect structure, disposed on the substrate;
a first passivation layer, disposed on the interconnect structure;
a stress buffer layer, disposed on the first passivation layer;
a pad structure, wherein the pad structure comprises:
a lower portion embedded in the first passivation layer and the stress buffer layer, and laterally wrapped by the first passivation layer and the stress buffer layer; and
an upper portion disposed on the lower portion, wherein the upper portion has a periphery laterally offset outward from a periphery of the lower portion, so that a bottom surface of the upper portion is in contact with a top surface of the stress buffer layer; and
a second passivation layer, disposed on the stress buffer layer and laterally wrapping the upper portion of the upper portion of the pad structure.

2. The semiconductor device of claim 1, wherein the second passivation layer further extends to cover a first portion of a top surface of the pad structure, and the second passivation layer has an opening exposing a second portion of the top surface of the pad structure.

3. The semiconductor device of claim 2, further comprising: a bump structure disposed in the opening to contact the second portion of the top surface of the pad structure.

4. The semiconductor device of claim 2, further comprising: a post-passivation interconnect (PPI) line disposed in the opening to contact the second portion of the top surface of the pad structure, and extending on a top surface of the second passivation layer.

5. The semiconductor device of claim 1, wherein a top surface of the pad structure is substantially level with a top surface of the second passivation layer.

6. The semiconductor device of claim 5, further comprising: a third passivation layer disposed on the second passivation layer, wherein the third passivation layer has an opening exposing a portion of a top surface of the pad structure.

7. The semiconductor device of claim 6, further comprising: a bump structure disposed in the opening to contact the portion of the top surface of the pad structure.

8. The semiconductor device of claim 1, wherein the stress buffer layer has a Young's modulus less than a Young's modulus of the first passivation layer and the second passivation layer.

9. A method of forming a semiconductor device, comprising:
forming an interconnect structure on a substrate;
forming a first passivation layer and a stress buffer layer on the interconnect structure;
forming a first opening in the first passivation layer and the stress buffer layer;
forming a pad structure on the stress buffer layer, wherein the pad structure has a lower portion in the first opening; and
forming a second passivation layer on the stress buffer layer, wherein the second passivation layer laterally wraps an upper portion of the pad structure.

10. The method of claim 9, wherein the forming the pad structure comprises:
forming a seed material on the stress buffer layer, wherein the seed material conformally cover a surface of the first opening;
forming a mask pattern with a second opening on the seed material, wherein the second opening exposes the seed material on the first opening;
forming a conductive material to fill in the first and second openings; and
removing the mask pattern and the seed material under the mask pattern to expose the stress buffer layer.

11. The method of claim 10, wherein the pad structure comprises:
a seed layer conformally covering the surface of the first opening and extending to cover a portion of a top surface of the stress buffer layer; and
a conductive layer formed on the seed layer.

12. The method of claim 10, wherein the second passivation layer is formed after forming the pad structure, the second passivation layer further extends to cover a first portion of a top surface of the pad structure, and a third opening is formed in the second passivation layer to expose a second portion of the top surface of the pad structure.

13. The method of claim 9, wherein the forming the pad structure comprises:
forming the second passivation layer on the stress buffer layer, wherein the second passivation layer has a second opening communicating with the first opening to form a composite opening;
forming a seed material to conformally cover a surface of the composite opening and a top surface of the second passivation layer;
forming a conductive material on the seed material, wherein the conductive material is filled in the composite opening; and
performing a planarization process to remove an excess portion of the seed material and the conductor material on the second passivation layer, thereby forming the pad structure in the composite opening.

14. The method of claim 13, wherein the pad structure comprises:
a conductive layer formed in the composite opening;
a seed layer extending between the conductive layer and the second passivation layer, extending between the conductive layer and the stress buffer layer, and extending between the conductive layer and the first passivation layer.

15. The method of claim 13, wherein a top surface of the pad structure is substantially level with a top surface of the second passivation layer.

16. The method of claim 13, further comprising:
forming a third passivation layer on the second passivation layer, wherein the third passivation layer has a third opening exposing a portion of a top surface of the pad structure; and
forming a bump structure in the third opening.

17. A package structure, comprising:
a first die comprising:
a first pad structure; and
a first protection structure laterally wrapping the first pad structure, wherein the first protection structure comprises a first stress buffer layer sandwiched between a first passivation layer and a second passivation layer, and the first stress buffer layer has a Young's modulus less than a Young's modulus of the first passivation layer and the second passivation layer; and
a second die comprising a second pad structure, wherein the first die and the second die are bonded together by directly contacting the first pad structure with the second pad structure.

18. The package structure of claim 17, wherein the second die further comprises a second protection structure, and the second protection structure comprises a second stress buffer layer sandwiched between a third passivation layer and a fourth passivation layer.

19. The package structure of claim 18, wherein the first protection structure is in direct contact with the second protection structure.

20. The package structure of claim 17, wherein the first pad structure comprises:
a lower portion embedded in the first passivation layer and the first stress buffer layer, and laterally wrapped by the first passivation layer and the first stress buffer layer; and
an upper portion disposed on the lower portion, wherein the upper portion has a periphery laterally offset outward from a periphery of the lower portion, so that a bottom surface of the upper portion is in contact with a top surface of the first stress buffer layer.
